(19) United States
(12) Patent Application Publication
(10) Pub. No.: US 2003/0085757 A1
(43) Pub. Date: May 8, 2003

(54) Semiconductor integrated circuit device

(76) Inventors: Kouji Ichikawa, Kariya-shi (JP); Yasuyuki Ishikawa, Kariya-shi (JP); Hideaki Ishihara, Okazaki-shi (JP)

Correspondence Address: POSZ & BETHARDS, PLC, 11250 ROGER BACON DRIVE, SUITE 10, RESTON, VA, 20190, US

(21) Appl. No.: 10/289,049

(22) Filed: Nov. 7, 2002

(30) Foreign Application Priority Data
Nov. 8, 2001 (JP) 2001-343137

(51) Int. Cl. H01L 25/00

(52) U.S. Cl. 327/564

(57) ABSTRACT

A first bypass capacitor interposes between an independent power supply line and an independent ground line provided in each of a plurality of circuit blocks. A second bypass capacitor interposes between a common power supply line and a common ground line.

### BACKGROUND OF THE INVENTION

The present invention relates to a semiconductor integrated circuit device including a semiconductor substrate and a plurality of circuit blocks provided on this substrate.

A one-chip microcomputer, serving as a semiconductor integrated circuit device, includes a plurality of circuit blocks, such as CPU, ROM, RAM, and others.

For example, a CPU (i.e., central processing unit) includes numerous transistors each repeating a switching operation in response to a clock signal. Accordingly, the CPU causes an increased amount of feedthrough current in the microcomputer.

Furthermore, a ROM (i.e., read only memory) or a RAM (i.e., random access memory) includes large-scale transistors serving as decoder buffers which also repeat the switching operations. Accordingly, like the CPU, both of the ROM and the RAM cause an increased amount of feedthrough current in the microcomputer.

The feedthrough current, caused in this manner in response to the clock signals, induces the fluctuation of electrical potential at an external terminal such as a power supply terminal or a ground terminal. The fluctuation of electrical potential is generally referred to as “bounce” which propagates as undesirable radiant noises to an external device via the external terminal of the microcomputer.

In addition to the feedthrough current flowing across the inside of each circuit block, the charging or discharging current for the transistors flows from one circuit block to others and propagates as undesirable radiant noises to the external device via the external terminal of the microcomputer.

### SUMMARY OF THE INVENTION

In view of the foregoing problems of the prior art, the present invention has an object to provide a semiconductor integrated circuit device capable of effectively suppressing the generation of undesirable radiant noises.

To accomplish the above and other related objects, the present invention provides a semiconductor integrated circuit device including a plurality of circuit blocks each having an independent power supply line and an independent ground line. A common power supply line extends from a power supply terminal of the semiconductor integrated circuit device to the independent power supply line of each of the plurality of circuit blocks. Similarly, a common ground line extends from a ground terminal of the semiconductor integrated circuit device to the independent ground line of each of the plurality of circuit blocks. A first bypass capacitor interposes between the independent power supply line and the independent ground line provided in each of the plurality of circuit blocks. A second bypass capacitor interposes between the common power supply line and the common ground line.

Preferably, the second bypass capacitor is disposed close to the plurality of circuit blocks and far from the power supply terminal and the ground line.

### BRIEF DESCRIPTION OF THE DRAWINGS

The above and other objects, features and advantages of the present invention will become more apparent from the following detailed description which is to be read in conjunction with the accompanying drawings, in which:

FIG. 1 is a circuit diagram showing the schematic arrangement of a plurality of circuit blocks provided in a microcomputer in accordance with a first embodiment of the present invention; and

FIG. 2 is a circuit diagram showing the schematic arrangement of a plurality of circuit blocks provided in a microcomputer in accordance with a second embodiment of the present invention.

### DESCRIPTION OF PREFERRED EMBODIMENTS

Preferred embodiments of the present invention will be explained hereinafter with reference to attached drawings.

### First Embodiment

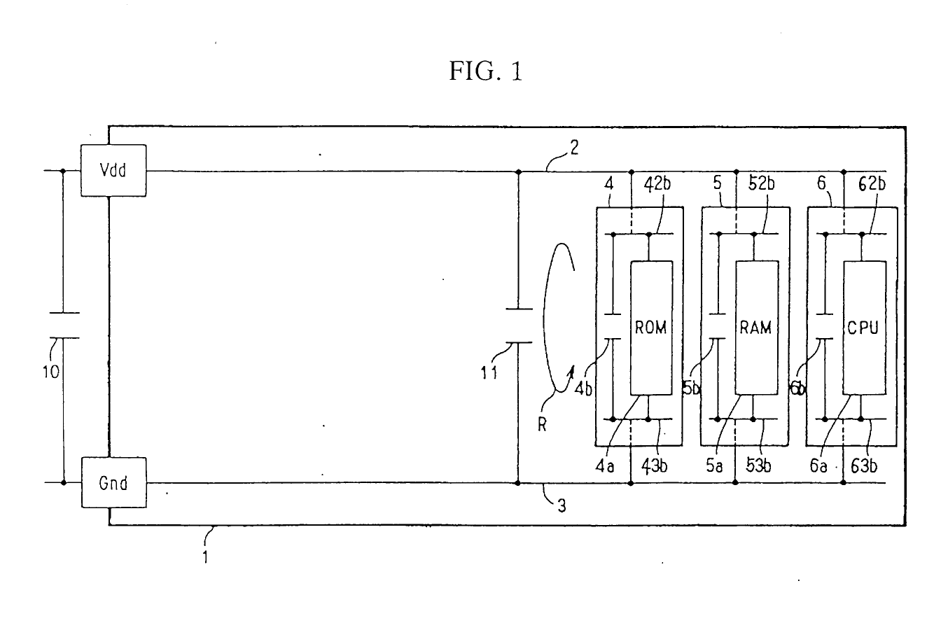

FIG. 1 shows a circuit arrangement of a microcomputer 1 serving as a semiconductor integrated circuit device in accordance with a first embodiment of the present invention.

In FIG. 1, the microcomputer 1 includes a power supply terminal Vdd and a ground terminal Gnd which respectively serve as external terminals of microcomputer 1.

A common power supply line 2, connected to the power supply terminal Vdd, extends in the microcomputer 1. Similarly, a common ground line 3 connected to the ground terminal Gnd extends in the microcomputer 1. The microcomputer 1 includes a total of three, i.e., first to third, circuit blocks 4, 5, and 6 each interposing between the common power supply line 2 and the common ground line 3.

The first circuit block 4 is located closest to the power supply terminal Vdd and the ground terminal Gnd. The third circuit block 6 is located farthest from the power supply terminal Vdd and the ground terminal Gnd.

The first circuit block 4 includes an independent power supply line 42b connected to the common power supply line 2, an independent ground line 43b connected to the common ground line 3, and a ROM circuit 4a interposing between the independent power supply line 42b and the independent ground line 43b.

The second circuit block 5 includes an independent power supply line 52b connected to the common power supply line 2, an independent ground line 53b connected to the common ground line 3, and a RAM circuit 5a interposing between the independent power supply line 52b and the independent ground line 53b.

The third circuit block 6 includes an independent power supply line 62b connected to the common power supply line 2, an independent ground line 63b connected to the common ground line 3, and a CPU circuit 6a interposing between the independent power supply line 62b and the independent ground line 63b.

Each of the first to third circuit blocks 4 to 6 is a functional circuit block constituted as an independent semiconductor circuit for performing required or designated functions.

The first circuit block 4, including the ROM circuit 4a, is a functional circuit block performing predetermined read only memory functions. The ROM circuit 4a stores the programs to be used in the information processing procedures performed by the microcomputer 1. Furthermore, the ROM circuit 4a stores various numerical data and character patterns.

The second circuit block 5, including the RAM circuit 5a, is a functional circuit block performing predetermined random access memory functions. The RAM circuit 5a temporarily stores various calculation or control data to be used in the calculating or controlling procedures performed by the microcomputer 1. In this respect, the RAM circuit 5a serves as a work area of the microcomputer 1.

The third circuit block 6, including the CPU circuit 6a, is a functional circuit block performing predetermined central processing unit functions. The CPU circuit 6a includes numerous arithmetic logic units for performing predetermined information processing procedures according to the programs stored in the ROM circuit 4a.

Furthermore, the first circuit bock 4 includes a first bypass capacitor 4b interposing between the independent power supply line 42b and the independent ground line 43b. The second circuit block 5 includes a first bypass capacitor 5b interposing between the independent power supply line 52b and the independent ground line 53b. The third circuit block 6 includes a first bypass capacitor 6b interposing between the independent power supply line 62b and the independent ground line 63b.

According to the circuit arrangement of the microcomputer 1 shown in FIG. 1, the feedthrough current caused in each of the first to third circuit blocks 4 to 6 returns or circulates via the corresponding first bypass capacitor 4b, 5b or 6b to the ROM circuit 4a, the RAM circuit 5a, or the CPU circuit 6a. This effectively prevents the undesirable radiant noises caused in the microcomputer 1 from propagating to the outside of the microcomputer 1 via the power supply terminal Vdd and the ground terminal Gnd.

Although not shown specifically in the drawing, each of the first bypass capacitors 4b, 5b and 6b can be formed as an oxide film spanning from one polysilicon capacitor electrode to the other electrode when the common power supply line 2 and the common ground line 3 are made of aluminum.

Furthermore, the circuit arrangement of the first embodiment includes an external bypass capacitor 10 provided outside the microcomputer 1. The external bypass capacitor 10, interposing between the power supply terminal Vdd and the ground terminal Gnd, suppresses the bounce (i.e., the fluctuation of electric potential) of the power source or ground potential appearing at the outside of the microcomputer 1.

The microcomputer 1 includes a second bypass capacitor 11 interposing between the common power supply line 2 and the common ground line 3. The second bypass capacitor 11 has one terminal connected to a predetermined portion of the common power supply line 2 extending from the power supply terminal Vdd to a terminal of the first circuit block 4 (i.e., a terminal connected to the independent power supply line 42b). The other terminal of the second bypass capacitor 11 is connected to a predetermined portion of the common ground line 3 extending from the ground terminal Gnd to the other terminal of the first circuit block 4 (i.e., a terminal connected to the independent ground line 43b).

The second bypass capacitor 11 forms a feedback route R in the microcomputer 1 for returning or circulating the charging or discharging current toward the first to third circuit blocks 4 to 6. This effectively prevents the charging or discharging current from propagating as the undesirable radiant noises to the outside of the microcomputer 1 via the power supply terminal Vdd and the ground terminal Gnd.

Furthermore, according to the circuit arrangement of the first embodiment, the second bypass capacitor 11 is positioned close to the first to third circuit blocks 4 to 6 and far from the power supply terminal Vdd and the ground terminal Gnd.

In other words, the impedance of a first region of the common power supply line 2 ranging from the power supply terminal Vdd to the one terminal of the second bypass capacitor 11 is larger than the impedance of a second region of the common power supply line 2 ranging from the one terminal of the second bypass capacitor 11 to any one of the first to third circuit blocks 4 to 6.

Similarly, the impedance of a first region of the common ground line 3 ranging from the ground terminal Gnd to the other terminal of the second bypass capacitor 11 is larger than the impedance of a second region of the common ground line 3 ranging from the other terminal of the second bypass capacitor 11 to any one of the first to third circuit blocks 4 to 6.

Thus, the first embodiment makes it possible to reduce the wiring impedance of the common power supply line 2 connecting the one terminal of the second bypass capacitor 11 to each of the first to third circuit blocks 4 to 6 as well as the wiring impedance of the common ground line 3 connecting the other terminal of the second bypass capacitor 11 to each of the first to third circuit blocks 4 to 6. Reducing the wiring impedance in this manner assures to further reduce or eliminate the charging or discharging current propagating as the undesirable radiant noises to the outside of the microcomputer 1 via the power supply terminal Vdd and the ground terminal Gnd.

### Second Embodiment

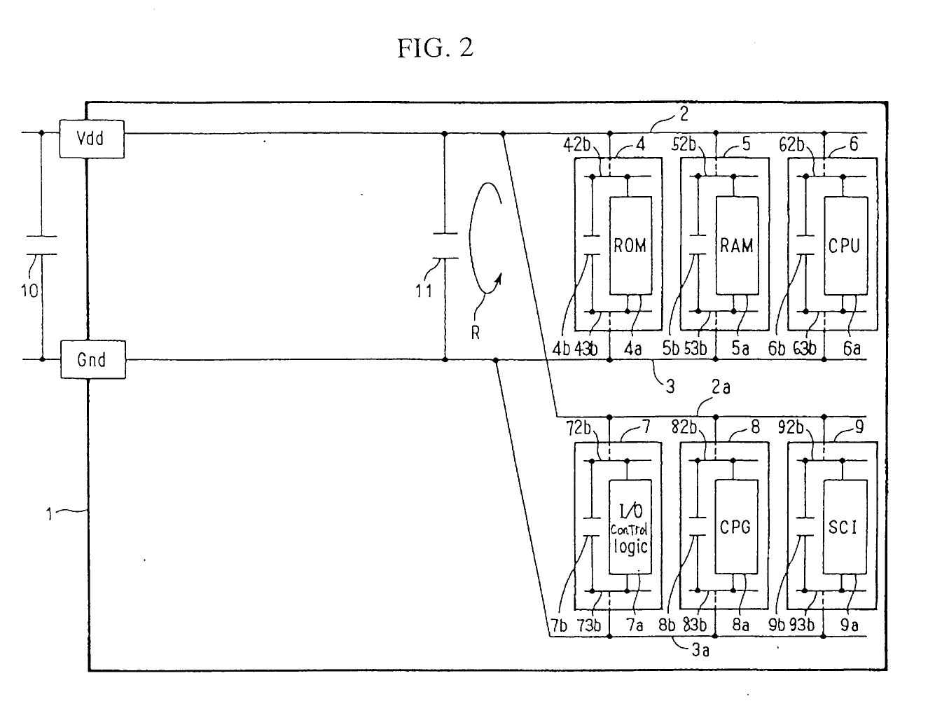

FIG. 2 shows another circuit arrangement of the microcomputer 1 serving as a semiconductor integrated circuit device in accordance with a second embodiment of the present invention.

In FIG. 2, the microcomputer 1 includes the power supply terminal Vdd and the ground terminal Gnd which serve as external terminals of microcomputer 1.

A primary power supply line 2 (corresponding to the common power supply line 2 shown in FIG. 1) is connected to the power supply terminal Vdd and extends in the microcomputer 1. Similarly, a primary ground line 3 (corresponding to the common ground line 3 shown in FIG. 1) is connected to the ground terminal Gnd and extends in the microcomputer 1. The microcomputer 1 includes first to third circuit blocks 4, 5, and 6 each interposing between the primary power supply line 2 and the primary ground line 3. In this respect, the primary power supply line 2 is a common power supply line for the first to third circuit blocks 4, 5, and 6. The primary ground line 3 is a common ground line for the first to third circuit blocks 4, 5, and 6.

Furthermore, a subsidiary power supply line 2a branches from the primary power supply line 2 and extends in the microcomputer 1. Similarly, a subsidiary ground line 3a branches from the primary ground line 3 and extends in the microcomputer 1. The microcomputer 1 includes another three, i.e., fourth to sixth, circuit blocks 7, 8, and 9 each interposing between the subsidiary power supply line 2a and the subsidiary ground line 3a. In this respect, the subsidiary power supply line 2a is a common power supply line for the fourth to sixth circuit blocks 7, 8 and 9. The subsidiary ground line 3a is a common ground line for the fourth to sixth circuit blocks 7, 8, and 9.

Each of the circuit blocks 4 through 9 is a functional circuit block constituted as an independent semiconductor circuit for performing required or designated functions.

The first circuit block 4 is located close to the power supply terminal Vdd and the ground terminal Gnd compared with the second circuit block 5. The third circuit block 6 is located far from the power supply terminal Vdd and the ground terminal Gnd compared with the second circuit block 5.

The fourth circuit block 7 is located close to the power supply terminal Vdd and the ground terminal Gnd compared with the fifth circuit block 8. The sixth circuit block 9 is located far from the power supply terminal Vdd and the ground terminal Gnd compared with the fifth circuit block 8.

The first circuit block 4 includes the independent power supply line 42b connected to the primary power supply line 2, the independent ground line 43b connected to the primary ground line 3, and the ROM circuit 4a interposing between the independent power supply line 42b and the independent ground line 43b.

The second circuit block 5 includes the independent power supply line 52b connected to the primary power supply line 2, the independent ground line 53b connected to the primary ground line 3, and the RAM circuit 5a interposing between the independent power supply line 52b and the independent ground line 53b.

The third circuit block 6 includes the independent power supply line 62b connected to the primary power supply line 2, the independent ground line 63b connected to the primary ground line 3, and the CPU circuit 6a interposing between the independent power supply line 62b and the independent ground line 63b.

The first circuit block 4, including the ROM circuit 4a, is a functional circuit block performing predetermined read only memory functions. The ROM circuit 4a stores the programs to be used in the information processing procedures performed by the microcomputer 1. Furthermore, the ROM circuit 4a stores various numerical data and character patterns.

The second circuit block 5, including the RAM circuit 5a, is a functional circuit block performing predetermined random access memory functions. The RAM circuit 5a temporarily stores various calculation or control data to be used in the calculating or controlling procedures performed by the microcomputer 1. In this respect, the RAM circuit 5a serves as a work area of the microcomputer 1.

The third circuit block 6, including the CPU circuit 6a, is a functional circuit block performing predetermined central processing unit functions. The CPU circuit 6a includes numerous arithmetic logic units for performing predetermined information processing procedures according to the programs stored in the ROM circuit 4a.

Furthermore, the first circuit bock 4 includes the first bypass capacitor 4b interposing between the independent power supply line 42b and the independent, ground line 43b. The second circuit block 5 includes the first bypass capacitor 5b interposing between the independent power supply line 52b and the independent ground line 53b. The third circuit block 6 includes the first bypass capacitor 6b interposing between the independent power supply line 62b and the independent ground line 63b.

The fourth circuit block 7 includes an independent power supply line 72b connected to the subsidiary power supply line 2a, an independent ground line 73b connected to the subsidiary ground line 3a, and an I/O control logic circuit 7a interposing between the independent power supply line 72b and the independent ground line 73b.

The fifth circuit block 8 includes an independent power supply line 82b connected to the subsidiary power supply line 2a, an independent ground line 83b connected to the subsidiary ground line 3a, and a CPG circuit 8a interposing between the independent power supply line 82b and the independent ground line 83b.

The sixth circuit block 9 includes an independent power supply line 92b connected to the subsidiary power supply line 2a, an independent ground line 93b connected to the subsidiary ground line 3a, and an SCI circuit 9a interposing between the independent power supply line 92b and the independent ground line 93b.

The fourth circuit block 7, including the I/O control logic circuit 7a, is a functional circuit block performing predetermined input/output buffer control logic functions. For example, the I/O control logic circuit 7a consists of an input buffer for fetching input data entered through an external terminal, an output buffer for generating an output signal to be sent out through the external terminal, and a control register for controlling an input mode of the input buffer as well as an output mode of the output buffer.

The fifth circuit block 8, including the CPG circuit 8a, is a functional circuit block performing clock pulse generation functions. The CPG circuit 8a generates a clock pulse used for the operations of internal circuits and also generates a reference time pulse used in a timer circuit or the like.

The sixth circuit block 9, including the SCI circuit 9a, is a functional circuit block performing serial communication interface functions. The SCI circuit 9a transmits and receives the data used in the serial communication.

Furthermore, the fourth circuit bock 7 includes a first bypass capacitor 7b interposing between the independent power supply line 72b and the independent ground line 73b. The fifth circuit block 8 includes a first bypass capacitor 8b interposing between the independent power supply line 82b and the independent ground line 83b. The sixth circuit block 9 includes a first bypass capacitor 9b interposing between the independent power supply line 92b and the independent ground line 93b.

According to the circuit arrangement of the microcomputer 1 shown in FIG. 2, the feedthrough current caused in each of the first to sixth circuit blocks 4 to 9 returns or circulates via the corresponding first bypass capacitor 4b, 5b, 6b, 7b, 8b, or 9b to the ROM circuit 4a, the RAM circuit 5a, the CPU circuit 6a, the I/O control logic circuit 7a, the CPG circuit 8a, or the SCI circuit 9a. This effectively prevents the undesirable radiant noises caused in the microcomputer 1 from propagating to the outside of the microcomputer 1 via the power supply terminal Vdd and the ground terminal Gnd.

Although not shown specifically in the drawing, each of the first bypass capacitors 4b, 5b, 6b, 7b, 8b, and 9b can be formed as an oxide film spanning from one polysilicon capacitor electrode to the other electrode when the power supply line 2 or 2a and the ground line 3 or 3a are made of aluminum.

The circuit arrangement of the second embodiment includes the external bypass capacitor 10 provided outside the microcomputer 1. The external bypass capacitor 10, interposing between the power supply terminal Vdd and the ground terminal Gnd, suppresses the bounce (i.e., the fluctuation of electric potential) of the power source or ground potential appearing at the outside the microcomputer 1.

The microcomputer 1 includes the second bypass capacitor 11 interposing between the primary power supply line 2 and the primary ground line 3. The second bypass capacitor 11 has one terminal connected to a predetermined portion of the primary power supply line 2 extending from the power supply terminal Vdd to a terminal of the first circuit block 4 (i.e., a terminal connected to the independent power supply line 42b). The other terminal of the second bypass capacitor 11 is connected to a predetermined portion of the primary ground line 3 extending from the ground terminal Gnd to the other terminal of the first circuit block 4 (i.e., a terminal connected to the independent ground line 43b).

The subsidiary power supply line 2a branches from a predetermined portion of the primary power supply line 2 positioned between the one terminal of the second bypass capacitor 11 and one terminal of the first circuit block 4 (i.e., the terminal connected to the independent power supply line 42b). The subsidiary ground line 3a branches from a predetermined portion of the primary ground line 3 positioned between the other terminal of the second bypass capacitor 11 and the other terminal of the first circuit block 4 (i.e., the terminal connected to the independent ground line 43b).

The second bypass capacitor 11 forms the feedback route R in the microcomputer 1 for returning or circulating the charging or discharging current toward the first to sixth circuit blocks 4 to 9. This effectively prevents the charging or discharging current from propagating as the undesirable radiant noises to the outside of the microcomputer 1 via the power supply terminal Vdd and the ground terminal Gnd.

Furthermore, according to the circuit arrangement of the second embodiment, the second bypass capacitor 11 is positioned close to the first to sixth circuit blocks 4 to 9 and far from the power supply terminal Vdd and the ground terminal Gnd.

In other words, the impedance of a first region of the primary power supply line 2 ranging from the power supply terminal Vdd to the one terminal of the second bypass capacitor 11 is larger than the impedance of a second region of the power supply line 2 or 2a ranging from the one terminal of the second bypass capacitor 11 to any one of the first to sixth circuit blocks 4 to 9.

Similarly, the impedance of a first region of the primary ground line 3 ranging from the ground terminal Gnd to the other terminal of the second bypass capacitor 11 is larger than the impedance of a second region of the ground line 3 or 3a ranging from the other terminal of the second bypass capacitor 11 to any one of the first to sixth circuit blocks 4 to 9.

Thus, the second embodiment makes it possible to reduce the wiring impedance of the power supply line 2 or 2a connecting the one terminal of the second bypass capacitor 11 to each of the first to sixth circuit blocks 4 to 9 as well as the wiring impedance of the ground line 3 or 3a connecting the other terminal of the second bypass capacitor 11 to each of the first to sixth circuit blocks 4 to 9. Reducing the wiring impedance in this manner assures to further reduce or eliminate the charging or discharging current propagating as the undesirable radiant noises to the outside of the microcomputer 1 via the power supply terminal Vdd and the ground terminal Gnd.

The present invention is not limited to the above-described first and second embodiments, and accordingly can be modified in various ways.

The above-described first and second embodiments are explained based on the semiconductor integrated circuit device including three or six circuit blocks therein. However, the number of the circuit blocks provided in the semiconductor integrated circuit device can be changed adequately depending on the specifications or requirements.

Similarly, the number of the power supply lines or the ground lines provided in the microcomputer 1 can be increased to three or more.

Application of the present invention is not limited to microcomputers. According, the present invention can be applied to any other semiconductor integrated circuit devices including a plurality of circuit blocks mounted on a semiconductor substrate.

As apparent from the foregoing description, the preferred embodiment of the present invention provides the semiconductor integrated circuit device (1) including a plurality of circuit blocks (4-9) each having the independent power supply line (42b-92b) and the independent ground line (43b-93b). The common power supply line (2, 2a) extends from the power supply terminal (Vdd) to the independent power supply line (42b-92b) of each of the plurality of circuit blocks (4-9). The common ground line (3, 3a) extends from the ground terminal (Gnd) to the independent ground line (43b-93b) of each of the plurality of circuit blocks (4-9). The first bypass capacitor (4b-9b) interposes between the independent power supply line (42b-92b) and the independent ground line (43b-93b) of each of the plurality of circuit blocks (4-9). And, the second bypass capacitor (11) interposes between the common power supply line (2, 2a) and the common ground line (3, 3a).

According to the arrangement of the above-described semiconductor integrated circuit device (1), the second bypass capacitor (11) returns or circulates the charging or discharging current when caused in the semiconductor integrated circuit device (1) toward the plurality of circuit blocks (4-9). This effectively prevents the charging or discharging current from propagating as the undesirable radiant noises to the outside of the semiconductor integrated circuit device (1) via the power supply terminal (Vdd) and the ground terminal (Gnd).

The second bypass capacitor (11) is disposed close to the plurality of circuit blocks (4-9) and far from the power supply terminal (Vdd) and the ground terminal (Gnd).

This is effective to reduce the wiring impedance of the power supply line portion extending from the second bypass capacitor (11) to each of the plurality of circuit blocks (4-9) as well as the wiring impedance of the ground line portion extending from the second bypass capacitor (11) to each of the of the plurality of circuit blocks (4-9). Reducing the wiring impedance assures further reduction or elimination of the charging or discharging current propagating as the undesirable radiant noises to the outside of the semiconductor integrated circuit device (1) via the power supply terminal (Vdd) and the ground terminal (Gnd).

The present embodiments as described are therefore intended to be only illustrative and not restrictive, since the scope of the invention is defined by the appended claims rather than by the description preceding them. All changes that fall within the metes and bounds of the claims, or equivalents of such metes and bounds, are therefore intended to be embraced by the claims.

What is claimed is:

1. A semiconductor integrated circuit device comprising:
a plurality of circuit blocks each having an independent power supply line and an independent ground line;
a common power supply line extending from a power supply terminal to said independent power supply line of each of said plurality of circuit blocks;
a common ground line extending from a ground terminal to said independent ground line provided in each of said plurality of circuit blocks;
a first bypass capacitor interposing between said independent power supply line and said independent ground line of each of said plurality of circuit blocks; and
a second bypass capacitor interposing between said common power supply line and said common ground line.

2. The semiconductor integrated circuit according to claim 1, wherein said second bypass capacitor is disposed close to said plurality of circuit blocks and far from said power supply terminal and said ground terminal.
